(19) United States
(12) Patent Application Publication
(10) Pub. No.: US 2026/0136729 A1
(43) Pub. Date: May 14, 2026

(54) HORIZONTAL LIGHT EMITTING DIODE AND MANUFACTURING METHOD THEREOF

(71) Applicant: Taiwan-Asia Semiconductor Corporation, Hsinchu City (TW)

(72) Inventors: Hong-Ta Cheng, Hsinchu City (TW); Ching-Yuan Tsai, Hsinchu City (TW); Yu-Tong Hsiao, Hsinchu City (TW)

(21) Appl. No.: 19/094,000

(22) Filed: Mar. 28, 2025

(30) Foreign Application Priority Data
Nov. 12, 2024 (TW) 113143311

(51) Int. Cl. H10H 20/857; H10H 20/01; H10H 20/824

(52) U.S. Cl. CPC H10H 20/857; H10H 20/0133; H10H 20/032; H10H 20/824

(57) ABSTRACT

A horizontal light-emitting diode (LED) and its manufacturing method are provided. The horizontal LED comprises a permanent substrate, an epitaxial composite layer, a first conductive-type electrode, a second conductive-type electrode, and an ohmic contact layer. The epitaxial composite layer includes a light-emitting layer with an emission wavelength in the range of 1100 to 2000 nanometers which is disposed on the permanent substrate. The first conductive-type electrode is disposed on the permanent substrate and electrically connected to the epitaxial composite layer. The second conductive-type electrode is disposed on the epitaxial composite layer, electrically connected to it, and is arranged on the same side of the permanent substrate as the first conductive-type electrode. The ohmic contact layer forms an ohmic contact with the first conductive-type electrode and is sandwiched between the epitaxial composite layer and the first conductive-type electrode. The thickness of the ohmic contact layer is no more than 1 micrometer.

### CROSS-REFERENCES TO RELATED APPLICATIONS

This application claims the benefit of priority to Taiwanese Patent Application No. 113143311 filed on Nov. 12, 2024, which is hereby incorporated by reference in its entirety.

### BACKGROUND OF THE INVENTION

### Field of the Invention

The present invention relates to a horizontal light-emitting diode and a manufacturing method thereof, in particular to a horizontal short-wave infrared light-emitting diode and a manufacturing method thereof.

### Descriptions of the Related Art

Light-emitting diodes (LEDs) offer advantages such as high brightness, small size, low power consumption, and long lifespan, making them widely used in lighting and display products. As shown in FIG. 1, a conventional horizontal red and infrared LED with an emission wavelength range of 590 to 1100 nanometers (nm) is illustrated. This horizontal LED comprises a sapphire substrate 10, a substrate bonding layer 11, a P-type gallium phosphide (GaP) epitaxial layer 12, an active layer 13, an N-type gallium phosphide epitaxial layer 14, an N-type electrode 15, and a P-type electrode 16.

Since both the P-type gallium phosphide epitaxial layer 12 and the N-type gallium phosphide epitaxial layer 14 are compound semiconductor layers with high doping concentrations, they can each form a good ohmic contact with the N-type and P-type electrodes, respectively. On the other hand, in conventional red and infrared horizontal LEDs, the P-type gallium phosphide epitaxial layer 12 typically has a thickness of 1 to 10 micrometers (μm). As a result, during the photolithographic etching process for the P-type electrode 16, the P-type gallium phosphide epitaxial layer 12 has sufficient thickness to facilitate precise control over the etching depth of the P-type electrode 16 into the P-type gallium phosphide epitaxial layer 12, thereby ensuring a smooth subsequent metal deposition process for the electrode.

However, the aforementioned horizontal LED epitaxial structure is not suitable for horizontal short-wavelength infrared (SWIR) LEDs with an emission wavelength range of 1100 to 2000 nanometers (nm). Therefore, there is an urgent need in the industry for an innovative horizontal LED structure and fabrication method to meet the development requirements of horizontal SWIR LEDs.

### SUMMARY OF THE INVENTION

The main objective of the present invention is to provide a high-brightness horizontal light-emitting diode (LED) and its manufacturing method, which is applicable to short-wavelength infrared (SWIR) LEDs with an emission wavelength range of 1100 to 2000 nanometers (nm). The LED structure disclosed in the present invention not only enables precise control over the etching stop depth of the P-type ohmic contact layer but also reduces the absorption of light emitted from the active layer. As a result, the brightness of the LED is enhanced, thereby expanding the scope of downstream product applications in the industry.

To achieve the above objective, the present invention discloses a horizontal LED which comprises a permanent substrate, an epitaxial composite layer, a first conductive-type electrode, a second conductive-type electrode, and an ohmic contact layer. The epitaxial composite layer includes a light-emitting layer with an emission wavelength in the range of 1100 to 2000 nanometers which is disposed on the permanent substrate. The first conductive-type electrode is disposed on the permanent substrate and electrically connected to the epitaxial composite layer. The second conductive-type electrode is disposed on the epitaxial composite layer, electrically connected to it, and is arranged on the same side of the permanent substrate as the first conductive-type electrode. The ohmic contact layer forms an ohmic contact with the first conductive-type electrode and is sandwiched between the epitaxial composite layer and the first conductive-type electrode. The thickness of the ohmic contact layer is no more than 1 micrometer.

In one embodiment of a horizontal light-emitting diode of the present invention, the ohmic contact layer is an indium gallium arsenide phosphide (InGaAsP) layer.

In one embodiment of a horizontal light-emitting diode of the present invention, the first conductive-type electrode includes a metal stack layer with a thickness smaller than 1 micrometer.

In one embodiment of a horizontal light-emitting diode of the present invention, the material of the metal stack layer is selected from one of the group consisting of titanium (Ti), platinum (Pt), gold (Au), palladium (Pd), germanium (Ge), zinc gold (ZnAu) and their combinations.

In one embodiment of a horizontal light-emitting diode of the present invention, the epitaxial composite layer further includes a first compound semiconductor layer and a second compound semiconductor layer, the first compound semiconductor layer and the second compound semiconductor layer sandwich the light-emitting layer, and the first compound semiconductor layer is disposed between the light-emitting layer and the ohmic contact layer.

In one embodiment of a horizontal light-emitting diode of the present invention, the first compound semiconductor layer is a first conductive-type indium phosphide (InP) layer, and the second compound semiconductor layer is a second conductive-type indium phosphide (InP) layer.

In one embodiment of a horizontal light-emitting diode of the present invention, the permanent substrate is one of a silicon substrate, an aluminum nitride substrate and a sapphire substrate.

In one embodiment of a horizontal light-emitting diode of the present invention, the horizontal light-emitting diode further comprises a substrate bonding layer sandwiched between the permanent substrate and the epitaxial composite layer, wherein the substrate bonding layer is one of an aluminum oxide (Al₂O₃) layer and a silicon dioxide (SiO₂) layer.

To achieve the above objective, the present invention discloses a manufacturing method of a horizontal light-emitting diode comprising the following steps: providing an epitaxial composite layer, disposed on a permanent substrate, including a light-emitting layer with an emission wavelength of 1100 to 2000 nanometers; providing an ohmic contact layer, disposed on the epitaxial composite layer, a thickness of the ohmic contact layer is no more than 1 micrometer; provide a metal stack layer, disposed on the ohmic contact layer to form ohmic contact with the ohmic contact layer; provide a substrate bonding layer covering the epitaxial composite layer and the metal stack layer; provide a permanent substrate for bonding the substrate bonding layer and removing the epitaxial growth substrate thereafter; and etching a portion of the ohmic contact layer and stopping etching at the metal stack layer to form an electrode trench.

In one embodiment of a manufacturing method of a horizontal light-emitting diode of the present invention, the step of providing an ohmic contact layer is to provide an indium gallium arsenide phosphide (InGaAsP) layer.

In one embodiment of a manufacturing method of a horizontal light-emitting diode of the present invention, the material of the metal stack layer is selected from one of the group consisting of titanium (Ti), platinum (Pt), gold (Au), palladium (Pd), germanium (Ge), zinc gold (ZnAu) and their combinations.

In one embodiment of a manufacturing method of a horizontal light-emitting diode of the present invention, the step of providing an epitaxial composite layer is to provide a first compound semiconductor layer and a second compound semiconductor layer, the first compound semiconductor layer and the second compound semiconductor layer sandwich the light-emitting layer, and the first compound semiconductor layer is disposed between the light-emitting layer and the ohmic contact layer.

In one embodiment of a manufacturing method of a horizontal light-emitting diode of the present invention, the step of providing a first compound semiconductor layer and a second compound semiconductor layer is to provide a first conductive-type indium phosphide (InP) layer and a second conductive-type indium phosphide (InP) layer.

In one embodiment of a manufacturing method of a horizontal light-emitting diode of the present invention, the step of providing a permanent substrate is to provide one of a silicon substrate, an aluminum nitride substrate and a sapphire substrate.

In one embodiment of a manufacturing method of a horizontal light-emitting diode of the present invention, the step of providing a substrate bonding layer is to provide one of an aluminum oxide (Al₂O₃) layer and a silicon dioxide (SiO₂) layer.

In one embodiment of a manufacturing method of a horizontal light-emitting diode of the present invention, the manufacturing method further includes a step of metal evaporation to form a first conductive-type electrode in the electrode trench.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram of a conventional horizontal red and infrared light-emitting diode;

FIG. 2A to FIG. 2G illustrate schematic diagrams of the manufacturing process of a horizontal light-emitting diode in an embodiment of the present invention;

FIG. 3 is a schematic diagram of a horizontal light-emitting diode in an embodiment of the present invention; and

FIG. 4 is a schematic diagram of the process steps for manufacturing a horizontal light-emitting diode in an embodiment of the present invention.

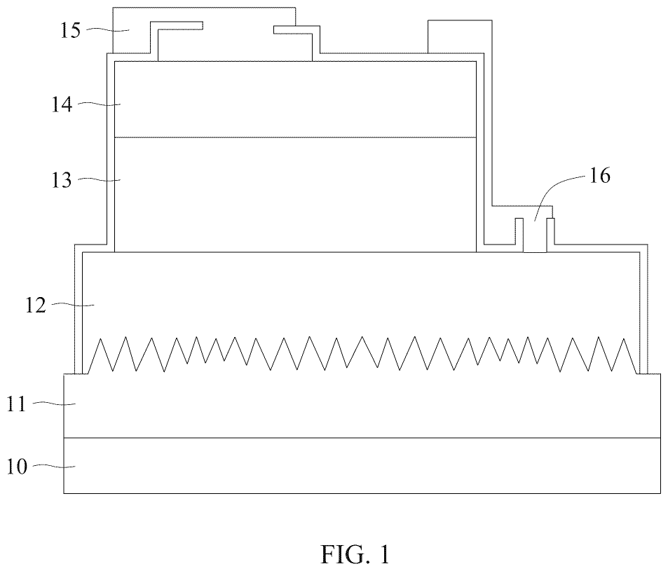

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

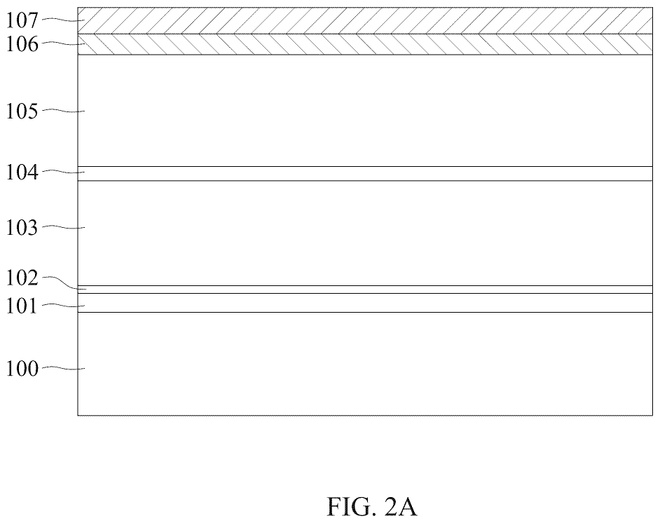

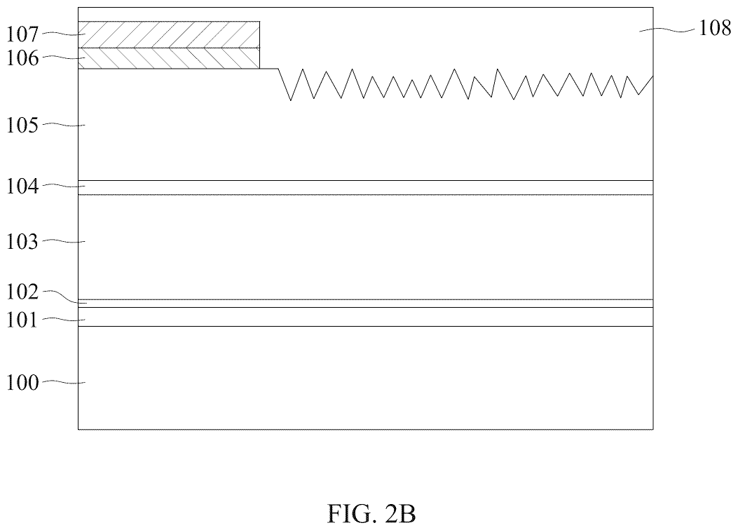

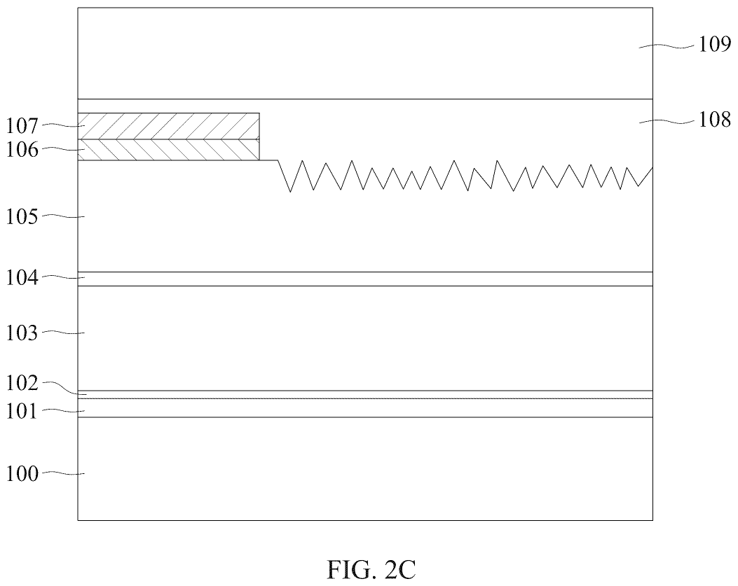

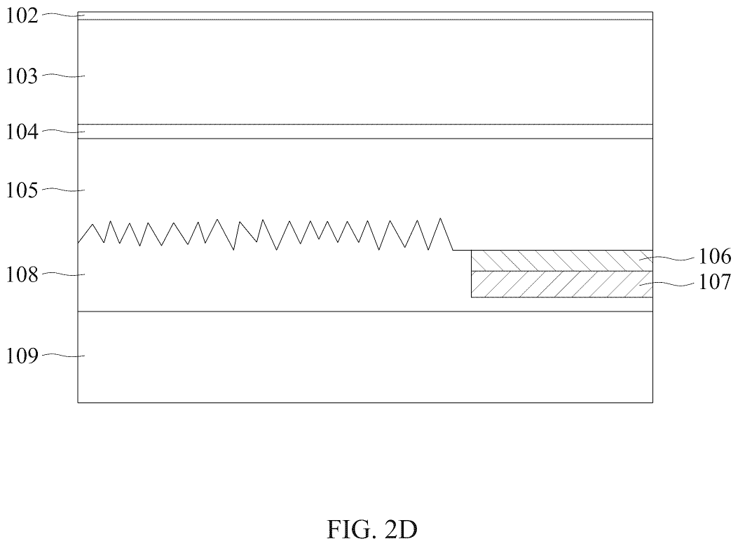

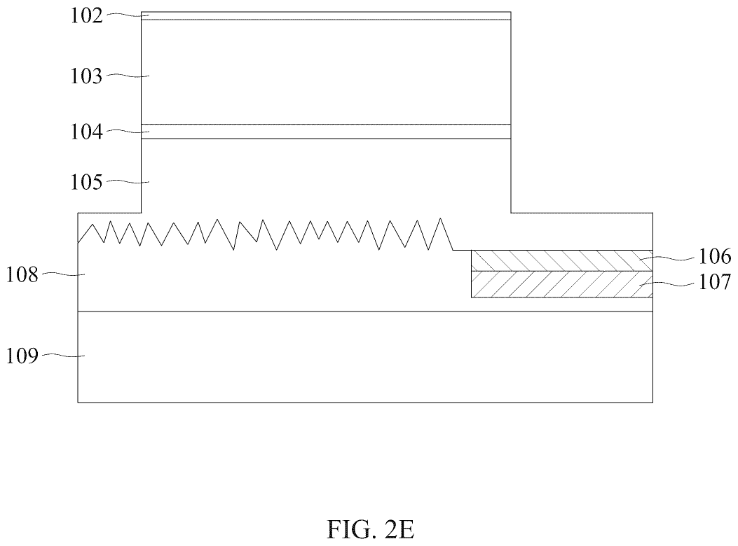

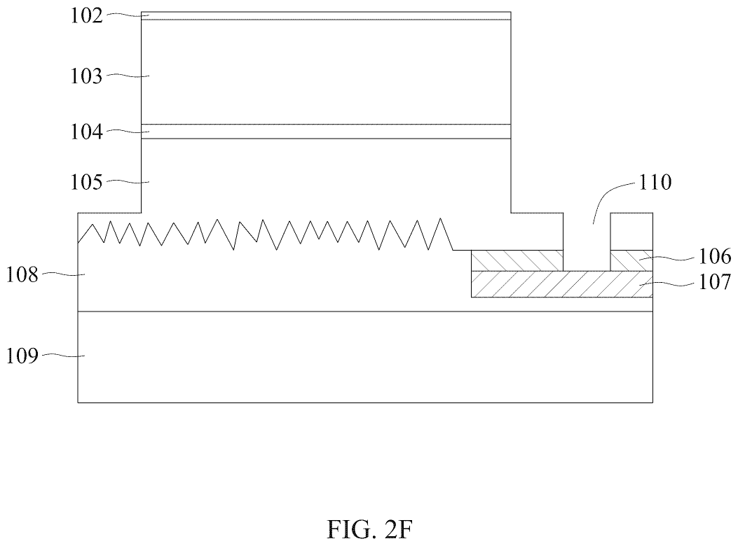

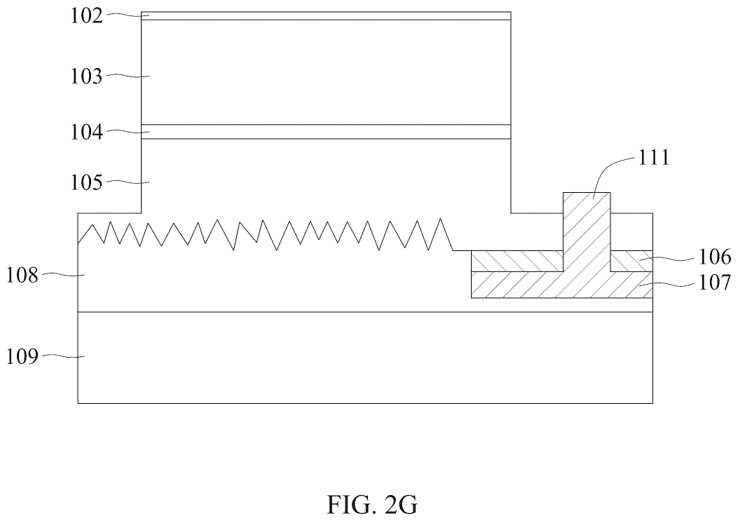

The present invention discloses a horizontal light-emitting diode (LED) and a method for manufacturing the same. Referring to FIG. 2A, an epitaxial buffer layer 101 and an N-type ohmic contact layer 102 are epitaxially grown on an epitaxial growth substrate 100 using Metal Organic Chemical Vapor Deposition (MOCVD) or Molecular Beam Epitaxy (MBE) technology. Specifically, the epitaxial growth substrate 100 is, but not limited to, an indium phosphide (InP) substrate. Furthermore, the buffer layer 101 is an N-type InP epitaxial layer, which serves to adjust the lattice matching between the epitaxial growth substrate and the subsequently grown epitaxial composite layers, thereby reducing stress induced by lattice mismatch and enhancing the film quality of the epitaxial layers formed in the following.

Next, the N-type ohmic contact layer 102 is specifically an N-type indium gallium arsenide (InGaAs) epitaxial layer, which has a lattice constant between that of indium phosphide (InP) and the multiple quantum well (MQW) structure. Therefore, the N-type InGaAs epitaxial layer can also function as a buffer layer to further adjust the lattice matching of subsequent epitaxial layers. Additionally, the N-type InGaAs epitaxial layer enhances carrier injection efficiency by tuning its bandgap according to the gallium-to-indium ratio, thereby optimizing the transport of electrons and holes to ensure effective carrier injection into the light-emitting layer and improving luminous efficiency. Specifically, the N-type ohmic contact layer 102 serves as an interface for ohmic contact with the N-type electrode. Thus, the common dopants used in the N-type InGaAs epitaxial layer include sulfur(S), selenium (Se), or silicon (Si), with doping concentrations typically ranging from 10¹⁸ to 10²⁰ cm⁻³. This doping range helps reduce the Schottky barrier for achieving low-resistance ohmic contact.

Subsequently, an epitaxial composite layer is grown on the N-type ohmic contact layer 102. This composite layer comprises a first compound semiconductor layer 105, a light-emitting layer 104, and a second compound semiconductor layer 103. The light-emitting layer 104 is a multiple quantum well (MQW) structure formed from quaternary indium gallium arsenide phosphide (InGaAsP), sandwiched between the first compound semiconductor layer 105 and the second compound semiconductor layer 103. In the present embodiment, the MQW emission wavelength ranges from 1100 nm to 2000 nm. Specifically, the first compound semiconductor layer 105 is a first conductivity-type (P-type) InP epitaxial layer, while the second compound semiconductor layer 103 is a second conductivity-type (N-type) InP epitaxial layer. It should be noted that the materials in the described embodiment are merely examples and not limited thereto. In practical applications, materials and compositions can be adjusted according to the emission wavelength, such as using aluminum gallium arsenide (AlGaAs) or indium gallium arsenide (InGaAs) for the epitaxial layers.

As shown in FIG. 2A, an additional compound semiconductor layer is epitaxially grown on the epitaxial composite layer. In a specific embodiment, this compound semiconductor layer is a P-type ohmic contact layer 106, such as a Zn-doped InGaAsP epitaxial layer, with a thickness not exceeding 1 micrometer (μm), preferably within 500-5000 angstroms (Å). Specifically, the doping concentration of the Zn-doped InGaAsP layer ranges from 10¹⁸ to 10²⁰ cm⁻³, which reduces contact resistance and forms an ohmic contact with the metal layer formed later. It is noted, for shortwave infrared (SWIR) LEDs with an emission wavelength of 1100-2000 nm, additional highly doped epitaxial layers are necessary to achieve good N-type and P-type ohmic contacts with the N-type and P-type electrodes. These include the N-type ohmic contact layer 102 (such as, the InGaAs epitaxial layer) and the P-type ohmic contact layer 106 (such as, the InGaAsP epitaxial layer). However, highly doped layers are narrow-bandgap materials that cause optical absorption and LED output reduction. To address this issue, the present invention significantly reduces the thickness of the SWIR LED's N-type and P-type ohmic contact layers to 1 μm below.

Next, a metal stack layer 107 is deposited on the P-type ohmic contact layer 106 using evaporation or sputtering. This metal stack layer 107 is made by one or more metals selected from a group consisted of titanium (Ti), platinum (Pt), gold (Au), palladium (Pd), germanium (Ge), zinc-gold (ZnAu), and their combinations with a thickness of less than 1 μm, preferably between 2000-5000 Å. The purpose of forming the metal stack layer 107 on the P-type ohmic contact layer 106 is to serve as an etch stop layer of the P-type ohmic contact layer 106 in subsequent processes for allowing precise control of the etching depth of the P-type electrode of the horizontal LED structure as described in the following.

Referring to FIG. 2B, a patterning process is performed on the metal stack layer 107 and the P-type ohmic contact layer 106 to expose a portion of the upper surface of the first compound semiconductor layer 105. Then, the exposed surface of the first compound semiconductor layer 105 undergoes roughening, that is the P-type InP epitaxial layer will be roughed, before depositing a substrate bonding layer 108. For example, as an alumina (Al₂O₃) or silicon dioxide (SiO₂) layer is deposited on the upper surface of the roughed first compound semiconductor layer 105 as the substrate bonding layer 108. As shown in FIG. 2C, wafer bonding is performed to bond the epitaxial growth substrate 100 to a permanent substrate 109, which can be, but not limited to, a silicon substrate, aluminum nitride substrate, or sapphire substrate. It is noted that the upper surface of the substrate bonding layer 108 is flattened to a certain extent to facilitate the smooth bonding of the epitaxial growth substrate to the permanent substrate during subsequent wafer bonding process. The total thickness of the metal stack 107 and the P-type ohmic contact layer 106 has to be properly controlled to prevent excessive thickness from affecting bonding strength. One technical feature of this invention is that, despite the thickness limitation to the metal stack layer 107 and the P-type ohmic contact layer 106, the metal stack layer 107 serves as an etching stop layer of the P-type ohmic contact layer 106 to overcome the issues of the prior art of failing to control the etching depth.

Referring to FIG. 2D, the epitaxial growth substrate 100 and the buffer layer 101 (such as, the N-type InP epitaxial layer) are removed from the opposite side of the permanent substrate 109 to expose the N-type ohmic contact layer 102 and to flip the wafer so the permanent substrate 109 is disposed at the bottom of the horizontal LED structure. Next, as shown in FIG. 2E, a mesa etching process is performed to partially etch the N-type ohmic contact layer 102 and the epitaxial composite layers. That is, a flat surface of the first compound semiconductor layer 105 is exposed for subsequent P-type electrode formation by partially etching the N-type ohmic contact layer 102, the first compound semiconductor layer 105, the light-emitting layer 104, and the second compound semiconductor layer 103.

Referring to FIG. 2F, a photolithography and etching process is performed on the first conductivity-type electrode for selectively etching a portion of the first compound semiconductor layer 105 and a portion of the P-type ohmic contact layer 106 while stopping at the metal stack layer 107 to precisely control the etching depth and form a patterned electrode groove 110 for subsequent electrode formation. Without the metal stack layer 107 as an etching stop layer in the LED structure during the manufacturing process thereof, controlling the etching depth of the P-type ohmic contact layer 106 would be challenging, affecting subsequent electrode formation for ohmic contact.

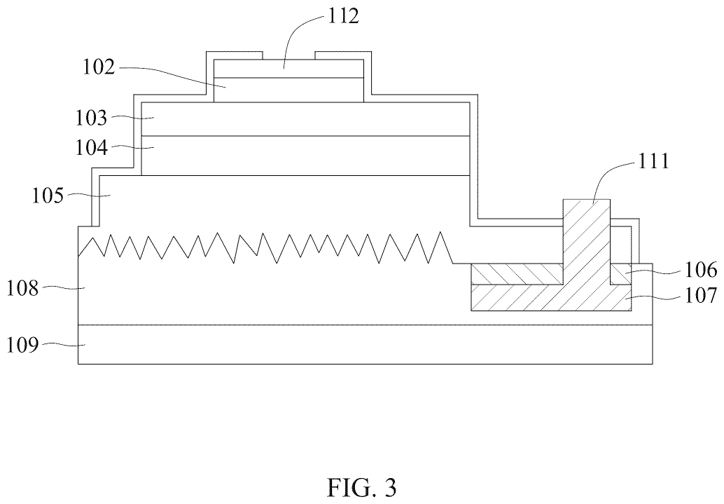

Referring to FIG. 2G, a metal evaporation process is performed to form the first conductivity-type electrode 111 within the electrode groove 110 for electrically connecting to the metal stack layer 107 and making the metal stack layer 107 as a part of the first conductivity-type electrode 111. The first conductivity-type electrode 111 is composed of the same material as the metal stack layer 107. On the other hand, a second conductivity-type electrode 112 is formed on the N-type ohmic contact layer 102 and electrically connected to the epitaxial composite layer. The second conductivity-type electrode 112 may be, for example, but not limited to, aluminum or gold-tin (AuSn) alloy. As shown in FIG. 3, a cross-sectional schematic of a horizontal SWIR LED in one embodiment of the present invention is illustrated, where the first conductivity-type electrode 111 and the second conductivity-type electrode 112 are disposed on the same side of the permanent substrate. One characteristic of the horizontal SWIR LED of the present invention is to arrange a metal stack layer disposed beneath the P-type ohmic contact layer as an etching stop layer. This design overcomes the challenge in horizontal LEDs operating in this wavelength range, where the ohmic contact layer must not be excessively thick while ensuring precise control of the etching depth of the ohmic contact layer.

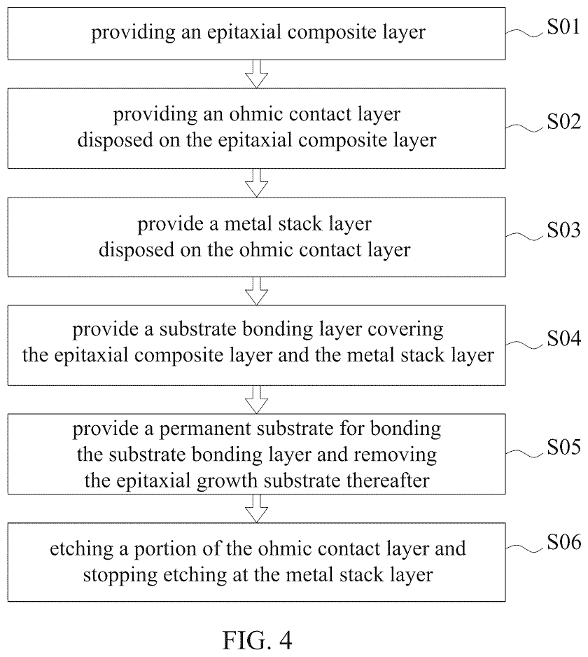

Referring to FIG. 4, a flowchart illustrates the manufacturing process of the horizontal LED according to the present invention. First, in step S01, an epitaxial composite layer is provided and formed on an epitaxial growth substrate. In step S02, an ohmic contact layer is provided on the epitaxial composite layer, wherein the thickness of the ohmic contact layer does not exceed 1 micrometer. Next, in step S03, a metal stack layer is provided on the ohmic contact layer for forming an ohmic contact with it. In step S04, a substrate bonding layer is applied to cover the epitaxial composite layer and the metal stack layer. In step S05, a permanent substrate is provided, bonded to the substrate bonding layer, followed by the removal of the epitaxial growth substrate. Finally, in step S06, a portion of the ohmic contact layer is etched and stop at the metal stack layer. Descriptions of the relevant components in the aforementioned process steps can be referenced in the preceding sections and will not be reiterated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A horizontal light-emitting diode, comprising:
a permanent substrate;
an epitaxial composite layer, including a light-emitting layer with an emission wavelength of 1100 to 2000 nanometers, disposed on the permanent substrate;
a first conductive-type electrode, disposed on the permanent substrate and electrically connected to the epitaxial composite layer;
a second conductive-type electrode, disposed on the epitaxial composite layer, electrically connected to the epitaxial composite layer, and arranged on the same side of the permanent substrate as the first conductive-type electrode; and
an ohmic contact layer, forming an ohmic contact with the first conductive-type electrode and sandwiched between the epitaxial composite layer and the first conductive-type electrode, wherein a thickness of the ohmic contact layer is no more than 1 micrometer.

2. The horizontal light-emitting diode of claim 1, wherein the ohmic contact layer is an indium gallium arsenide phosphide (InGaAsP) layer.

3. The horizontal light-emitting diode of claim 1, wherein the first conductive-type electrode includes a metal stack layer with a thickness smaller than 1 micrometer.

4. The horizontal light-emitting diode of claim 3, wherein the material of the metal stack layer is selected from one of the group consisting of titanium (Ti), platinum (Pt), gold (Au), palladium (Pd), germanium (Ge), zinc gold (ZnAu) and their combinations.

5. The horizontal light-emitting diode of claim 1, wherein the epitaxial composite layer further includes a first compound semiconductor layer and a second compound semiconductor layer, the first compound semiconductor layer and the second compound semiconductor layer sandwich the light-emitting layer, and the first compound semiconductor layer is disposed between the light-emitting layer and the ohmic contact layer.

6. The horizontal light-emitting diode of claim 5, wherein the first compound semiconductor layer is a first conductive-type indium phosphide (InP) layer, and the second compound semiconductor layer is a second conductive-type indium phosphide (InP) layer.

7. The horizontal light-emitting diode of claim 1, wherein the permanent substrate is one of a silicon substrate, an aluminum nitride substrate and a sapphire substrate.

8. The horizontal light-emitting diode of claim 1, further comprising a substrate bonding layer sandwiched between the permanent substrate and the epitaxial composite layer, wherein the substrate bonding layer is one of an aluminum oxide (Al₂O₃) layer and a silicon dioxide (SiO₂) layer.

9. A manufacturing method of a horizontal light-emitting diode, comprising:
providing an epitaxial composite layer, disposed on a permanent substrate, including a light-emitting layer with an emission wavelength of 1100 to 2000 nanometers;
providing an ohmic contact layer, disposed on the epitaxial composite layer, a thickness of the ohmic contact layer is no more than 1 micrometer;
provide a metal stack layer, disposed on the ohmic contact layer to form ohmic contact with the ohmic contact layer;
provide a substrate bonding layer covering the epitaxial composite layer and the metal stack layer;
provide a permanent substrate for bonding the substrate bonding layer and removing the epitaxial growth substrate thereafter; and
etching a portion of the ohmic contact layer and stopping etching at the metal stack layer to form an electrode trench.

10. The manufacturing method of a horizontal light-emitting diode of claim 9, wherein the step of providing an ohmic contact layer is to provide an indium gallium arsenide phosphide (InGaAsP) layer.

11. The manufacturing method of a horizontal light-emitting diode of claim 9, wherein the material of the metal stack layer is selected from one of the group consisting of titanium (Ti), platinum (Pt), gold (Au), palladium (Pd), germanium (Ge), zinc gold (ZnAu) and their combinations.

12. The manufacturing method of a horizontal light-emitting diode of claim 9, wherein the step of providing an epitaxial composite layer is to provide a first compound semiconductor layer and a second compound semiconductor layer, the first compound semiconductor layer and the second compound semiconductor layer sandwich the light-emitting layer, and the first compound semiconductor layer is disposed between the light-emitting layer and the ohmic contact layer.

13. The manufacturing method of a horizontal light-emitting diode of claim 12, wherein the step of providing a first compound semiconductor layer and a second compound semiconductor layer is to provide a first conductive-type indium phosphide (InP) layer and a second conductive-type indium phosphide (InP) layer.

14. The manufacturing method of a horizontal light-emitting diode of claim 9, wherein the step of providing a permanent substrate is to provide one of a silicon substrate, an aluminum nitride substrate and a sapphire substrate.

15. The manufacturing method of a horizontal light-emitting diode of claim 9, wherein the step of providing a substrate bonding layer is to provide one of an aluminum oxide (Al₂O₃) layer and a silicon dioxide (SiO₂) layer.

16. The manufacturing method of a horizontal light-emitting diode of claim 9, further including a step of metal evaporation to form a first conductive-type electrode in the electrode trench.
